(19) United States
(12) Patent Application Publication
(10) Pub. No.: US 2026/0140203 A1
(43) Pub. Date: May 21, 2026

(54) METHOD AND SYSTEM FOR TESTING SHORT-CIRCUIT WITHSTAND CAPABILITY OF TRANSFORMER, TERMINAL, MEDIUM, AND PROGRAM

(71) Applicants: GUANGDONG POWER GRID CO., LTD., Guangzhou (CN); ELECTRIC POWER RESEARCH INSTITUTE OF GUANGDONG POWER GRID CO., LTD., Guangzhou (CN)

(72) Inventors: Zhongxiang Li, Guangzhou (CN); Linglong Cai, Guangzhou (CN); Zhiqin Ma, Guangzhou (CN); Zhonghuan Su, Guangzhou (CN); Chunyao Lin, Guangzhou (CN); Dan Zhou, Guangzhou (CN); Zhongao Wang, Guangzhou (CN); Duanjiao Li, Guangzhou (CN); Zhangquan Rao, Guangzhou (CN); Xiaoguang Zheng, Guangzhou (CN); Xian Yang, Guangzhou (CN); Wenxing Sun, Guangzhou (CN); Bing Zhao, Guangzhou (CN); Aihui Wen, Guangzhou (CN); Zihao Liao, Guangzhou (CN); Haoru Ning, Guangzhou (CN); Lijun Tan, Guangzhou (CN); Shuo Jiang, Guangzhou (CN)

(21) Appl. No.: 19/448,011

(22) Filed: Jan. 13, 2026

Related U.S. Application Data
(63) Continuation-in-part of application No. PCT/CN2024/140488, filed on Dec. 19, 2024.

(30) Foreign Application Priority Data
Jul. 19, 2024 (CN) 202410974770.X

(51) Int. Cl. G01R 31/62; G01R 31/52

(52) U.S. Cl. CPC G01R 31/62; G01R 31/52

(57) ABSTRACT

Provided are a method and system for testing a short-circuit withstand capability of a transformer, a terminal, a medium, and a program. The method includes: acquiring a transformer design parameter and an operating condition of a power system where a transformer is located; acquiring a maximum short-circuit current passing through a transformer winding based on the transformer design parameter and the operating condition of the power system; inputting the maximum short-circuit current passing through the transformer winding into a first preset calculation model, and acquiring a first stress value for each disc of the transformer winding; acquiring a second stress value for each disc of the transformer winding by using a first predetermined method; acquiring an allowable current of the transformer winding by using a second predetermined method; acquiring a safety factor of the transformer, and determining a short-circuit withstand capability of the transformer.

### CROSS-REFERENCE TO RELATED APPLICATION

The present disclosure is a continuation-in-part of International Patent Application No. PCT/CN2024/140488, filed on Dec. 19, 2024, and claims priority to Chinese Patent Application No. 202410974770.X, filed with the China National Intellectual Property Administration (CNIPA) on Jul. 19, 2024, and entitled “METHOD AND SYSTEM FOR TESTING SHORT-CIRCUIT WITHSTAND CAPABILITY OF TRANSFORMER, TERMINAL, MEDIUM, AND PROGRAM”. Both of the foregoing applications are incorporated herein by reference in their entireties.

### TECHNICAL FIELD

The present disclosure relates to the field of transformer testing, and in particular to a method and system for testing a short-circuit withstand capability of a transformer, a terminal, a medium, and a program.

### BACKGROUND

The reliable operation of power transformers plays a crucial role in the safety and stability of power systems. When an outlet short-circuit occurs for the power transformer, an enormous short-circuit electrodynamic force may cause damage to conductor insulation or structural components. In severe cases, this can lead to winding loosening, twisting, and deformation, or even the collapse or burnout of the entire winding, resulting in incalculable economic losses and social impact.

Currently, the short-circuit withstand capability of power transformers is primarily tested using three methods. First, short-circuit tests are directly conducted on the transformer itself. However, the requirements for test conditions and costs are extremely high, which is not conducive to widespread promotion and application. Second, short-circuit tests are conducted via sampling inspection. While this method reduces testing costs to some extent, its coverage is limited, posing significant potential risks. Third, verification testing is conducted on the short-circuit withstand capability of the transformer, and conventional verification testing is based on effective radial support.

However, during the actual design and manufacturing process of transformers, certain assembly gaps exist between windings, and shrinkage of the insulating material is inevitable during the drying process. Consequently, during actual operation of the transformers, the strips intended for radial support and insulation cannot provide effective support. This leads to significant inaccuracies in the results acquired by the conventional verification testing method based on effective radial support. As a result, the accuracy in determining the transformer's short-circuit withstand capability is low, imposing substantial risks to the quality assurance and control of transformer equipment and the reliable operation of power systems.

### SUMMARY

The present disclosure provides a method and system for testing a short-circuit withstand capability of a transformer, a terminal, a medium, and a program, aiming to solve the technical problem in the prior art where the verification testing method based on effective radial support yields results with significant inaccuracies.

To solve the above technical problem, an embodiment of the present disclosure provides a method and system for testing a short-circuit withstand capability of a transformer, a terminal, a medium, and a program. The method includes:
acquiring a transformer design parameter and an operating condition of a power system where a transformer is located;
acquiring a maximum short-circuit current passing through a transformer winding based on the transformer design parameter and the operating condition of the power system where the transformer is located;
inputting the maximum short-circuit current passing through the transformer winding into a first preset calculation model, and acquiring a first stress value for each disc of the transformer winding, where the first preset calculation model is determined based on the transformer design parameter;
acquiring a second stress value for each disc of the transformer winding by using a first predetermined method based on the transformer design parameter;
acquiring an allowable current of the transformer winding by using a second predetermined method based on the first stress value for each disc of the transformer winding and the second stress value for each disc of the transformer winding;
acquiring a safety factor of the transformer based on the allowable current of the transformer winding and the maximum short-circuit current passing through the transformer winding;
determining a short-circuit withstand capability of the transformer based on the safety factor of the transformer; and
controlling the transformer to shut down at a preset time in response to that the short-circuit withstand capability of the transformer is unqualified.

Thus, by acquiring the transformer design parameter and the operating condition of the power system where the transformer is located, the maximum short-circuit current passing through the transformer winding is acquired. The maximum short-circuit current passing through the transformer is acquired based on the specific transformer design parameter and the voltage, current, and impedance of the power system where the transformer is located. This design enables more accurate testing of the short-circuit withstand capability of the transformer. Then, the acquired maximum short-circuit current passing through the transformer winding is input into the first preset calculation model, i.e., a finite element structural model to acquire the corresponding first stress value for each disc of the transformer winding. This improves calculation accuracy, reduces calculation errors, and enhances computational efficiency. Subsequently, the second stress value for each disc of the transformer winding is acquired through the first predetermined method, enabling effective testing of the short-circuit withstand capability of the transformer. The allowable current is then acquired through the second predetermined method to acquire the safety factor of the transformer. By determining whether the safety factor exceeds a first threshold, the qualification of the short-circuit withstand capability of the transformer is determined. This allows for low-cost and high-efficiency determination of the short-circuit withstand capability of the transformer. In response to that the short-circuit withstand capability of the transformer is unqualified, the transformer is controlled to shut down at the preset time, thereby effectively reducing the risk of operation failures in the power system.

In a preferred solution, the transformer design parameter includes a rated current of the transformer winding and a short-circuit impedance of the transformer; the operating condition of the power system where the transformer is located includes a short-circuit impedance of a grid system; and the maximum short-circuit current passing through the transformer winding is calculated by:

$${I}_{m} = {I}_{N} \times \frac{100}{{Z}_{T} + {Z}_{S}}$$

where, Iₘ denotes the maximum short-circuit current passing through the transformer winding; I_{N} denotes the rated current of the transformer winding; Z_{T} denotes the short-circuit impedance of the transformer; and Z_{S} denotes the short-circuit impedance of the grid system.

Thus, the maximum through-fault current experienced by the transformer winding under a short-circuit condition is acquired based on the short-circuit impedance of the grid system, the rated current of the transformer winding, and the short-circuit impedance of the transformer. This allows for a specific analysis on the short-circuit withstand capability of the transformer according to actual conditions, thereby improving calculation accuracy.

In a preferred solution, the transformer design parameter includes an iron core structure parameter, a winding structure parameter based on ineffective radial support, a clamping structure parameter, and an oil tank parameter; and the first preset calculation model is a finite element structural model;

the finite element structural model is established based on the iron core structure parameter, the winding structure parameter based on ineffective radial support, the clamping structure parameter, and the oil tank parameter; and

the inputting the maximum short-circuit current passing through the transformer winding into a first preset calculation model, and acquiring a first stress value for each disc of the transformer winding includes:

inputting the maximum short-circuit current passing through the transformer winding into the finite element structural model, and acquiring the first stress value for each disc of the transformer winding.

Thus, the corresponding finite element structural model is established based on the iron core structure parameter of the transformer, the winding structure parameter based on ineffective radial support, the clamping structure parameter, and the oil tank parameter. This enables accurate calculation of the first stress value through finite element analysis software, reducing computational time, improving work efficiency, and enhancing the accuracy of testing results.

In a preferred solution, the transformer design parameter includes a yield strength and a thickness of a transformer conductor; and the second stress value for each disc of the transformer winding is determined according to:

$${σ}_{l} = ( A {σ}_{0.2} + B ) ln {b}_{e q} + C$$

where, σ₁ denotes the second stress value for each disc of the transformer winding; σ_{0.2} denotes the yield strength of the transformer conductor; b_{eq} denotes the thickness of the transformer conductor; and A, B, and C are preset coefficients.

Thus, based on the yield strength and the thickness of the transformer conductor and the preset coefficients, the corresponding stress value can be calculated more accurately.

In a preferred solution, the preset coefficient A ranges from 0.13 to 0.15; the preset coefficient B ranges from 6 to 8; and the preset coefficient C ranges from 12 to 15.

Thus, the preset coefficients set within specific numerical ranges for the corresponding calculations enables more accurate testing of the short-circuit withstand capability of the transformer.

In a preferred solution, the acquiring an allowable current of the transformer winding by using a second predetermined method based on the first stress value for each disc of the transformer winding and the second stress value for each disc of the transformer winding specifically includes:
taking the maximum short-circuit current passing through the transformer winding as an estimated allowable current;
determining whether the first stress value for each disc of the transformer winding equals the second stress value for each disc of the transformer winding;
taking the estimated allowable current as the allowable current in response to that the first stress value for each disc of the transformer winding equals the second stress value for each disc of the transformer winding;
updating the estimated allowable current in response to that the first stress value for each disc of the transformer winding does not equal the second stress value for each disc of the transformer winding; and
inputting an updated estimated allowable current into the first preset calculation model, acquiring an updated first stress value for each disc of the transformer winding, and returning to the step of determining whether the first stress value for each disc of the transformer winding equals the second stress value for each disc of the transformer winding, until the first stress value for each disc of the transformer winding equals the second stress value for each disc of the transformer winding.

Thus, the corresponding estimated allowable current is acquired based on the first stress value, and then the accurate allowable current is acquired through the first preset calculation model. This design reduces the user's computational time and improves work efficiency.

In a preferred solution, the acquiring a safety factor of the transformer based on the allowable current of the transformer winding and the maximum short-circuit current passing through the transformer winding is specifically implemented according to:

$$K = \frac{{I}_{2}}{{I}_{m}}$$

where, K denotes the safety factor; I₂ denotes the allowable current; and Iₘ denotes the maximum short-circuit current passing through the winding.

This allows for a more accurate representation of the safety factor, reducing errors caused by simulation and calculation.

In a preferred solution, the determining a short-circuit withstand capability of the transformer based on the safety factor of the transformer specifically includes:
determining that the short-circuit withstand capability of the transformer is qualified in response to that the safety factor of the transformer is greater than a first threshold; and
determining that the short-circuit withstand capability of the transformer is unqualified in response that the safety factor of the transformer is less than the first threshold.

Thus, a higher safety factor of the transformer indicates a stronger short-circuit withstand capability and a higher safety factor. Expressing the safety factor of the transformer in numerical form provides the user with a more intuitive understanding.

An embodiment of the present disclosure further provides a system for testing a short-circuit withstand capability of a transformer, including: an acquisition module, a first calculation module, a second calculation module, a third calculation module, a fourth calculation module, a fifth calculation module, a determination module, and a control module, where
the acquisition module is configured to acquire a transformer design parameter and an operating condition of a power system where a transformer is located;
the first calculation module is configured to acquire a maximum short-circuit current passing through a transformer winding based on the transformer design parameter and the operating condition of the power system where the transformer is located;
the second calculation module is configured to input the maximum short-circuit current passing through the transformer winding into a first preset calculation model and acquire a first stress value for each disc of the transformer winding, where the first preset calculation model is determined based on the transformer design parameter;
the third calculation module is configured to acquire a second stress value for each disc of the transformer winding by using a first predetermined method based on the transformer design parameter;
the fourth calculation module is configured to acquire an allowable current of the transformer winding by using a second predetermined method based on the first stress value for each disc of the transformer winding and the second stress value for each disc of the transformer winding;
the fifth calculation module is configured to acquire a safety factor of the transformer based on the allowable current of the transformer winding and the maximum short-circuit current passing through the transformer winding;
the determination module is configured to determine a short-circuit withstand capability of the transformer based on the safety factor of the transformer; and
the control module is configured to control the transformer to shut down at a preset time in response to that the short-circuit withstand capability of the transformer is unqualified.

Thus, the acquisition module acquires the transformer design parameter and the operating condition of the power system where the transformer is located, and then the first calculation module acquires the maximum short-circuit current passing through the transformer winding. On this basis, the maximum short-circuit current passing through the transformer is calculated based on the specific transformer design parameter and the voltage, current, and impedance of the power system. This enables more accurate testing of the short-circuit withstand capability of the transformer. Then, the second calculation module inputs the acquired maximum short-circuit current into the first preset calculation model, i.e., a finite element structural model, to acquire the corresponding first stress value for each disc of the transformer winding. This improves calculation accuracy, reduces calculation errors, and enhances computational efficiency. The third calculation module acquires the second stress value for each disc of the transformer winding, enabling effective testing of the short-circuit withstand capability of the transformer. The fourth calculation module acquires the allowable current, and then the fifth calculation module acquires the safety factor of the transformer. The determination module determines whether the safety factor exceeds a first threshold to determine the qualification of the short-circuit withstand capability of the transformer. This allows for low-cost and high-efficiency determination of the short-circuit withstand capability of the transformer. In response to that the short-circuit withstand capability of the transformer is unqualified, the transformer is controlled to shut down at the preset time, thereby effectively reducing the risk of operation failures in the power system.

An embodiment of the present disclosure further provides a terminal device, including a processor, a memory, and a computer program stored in and run on the memory, where the processor is configured to execute the computer program, thereby implementing the steps of the method for testing a short-circuit withstand capability of a transformer described in any embodiment of the present disclosure.

An embodiment of the present disclosure further provides a non-transitory computer-readable storage medium, configured to store a computer program, where the computer program is executed by a processor to implement the steps of the method for testing a short-circuit withstand capability of a transformer described in any embodiment of the present disclosure.

An embodiment of the present disclosure further provides a computer program product, including a non-transitory computer-readable storage medium with computer-readable program code, where the computer-readable program code is executed by a processor to implement the steps of the method for testing a short-circuit withstand capability of a transformer described in any embodiment of the present disclosure.

### BRIEF DESCRIPTION OF THE DRAWINGS

FIG. 1 is a flowchart of an embodiment of a method for testing a short-circuit withstand capability of a transformer provided by the present disclosure;

FIG. 2 is a structural diagram of an embodiment of a system for testing a short-circuit withstand capability of a transformer provided by the present disclosure;

FIG. 3 is a curve diagram of a radial critical stress based on ineffective radial support in an embodiment of the method for testing a short-circuit withstand capability of a transformer provided by the present disclosure;

FIG. 4 is a diagram showing a critical state of a transformer winding subjected to an allowable current in an embodiment of the method for testing a short-circuit withstand capability of a transformer provided by the present disclosure; and

FIG. 5 is a schematic diagram of a short circuit of a transformer provided in the present disclosure.

Reference Numerals: 100. acquisition module; 200. first calculation module; 300. second calculation module; 400. third calculation module; 500. fourth calculation module; 600. fifth calculation module; 700. determination module; and 800. control module.

### DETAILED DESCRIPTION

The technical solutions of the embodiments of the present disclosure are clearly and completely described below with reference to the drawings in the embodiments of the present disclosure. Apparently, the described embodiments are merely a part rather than all of the embodiments of the present disclosure. All other embodiments obtained by those of ordinary skill in the art based on the embodiments of the present disclosure without creative efforts shall fall within the protection scope of the present disclosure.

### Embodiment 1

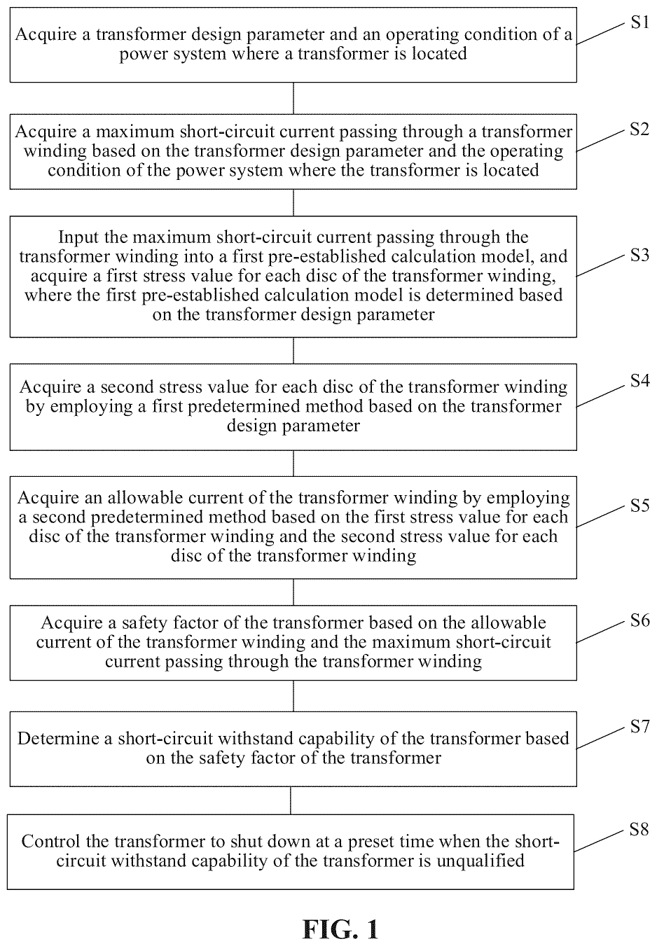

Please refer to FIG. 1, which is a flowchart of an embodiment of a method for testing a short-circuit withstand capability of a transformer provided by the present disclosure, including steps S1 to S7, specifically as follows.

S1. A transformer design parameter and an operating condition of a power system where a transformer is located are acquired.

In this embodiment, by acquiring the transformer design parameter and the operating condition of the power system where the transformer is located, a specific analysis can be performed on the specific parameters of the transformer, improving the accuracy of short-circuit withstand capability testing. Then the operating condition of the power system where the transformer is located is combined, providing a realistic basis for the accurate testing of the short-circuit withstand capability, ensuring that the calculation results are targeted and practically relevant.

In a specific embodiment, taking a transformer model SSZ-40000/110 as an example, the transformer features a rated voltage of 121/40.5/10.5 kV, a connection group of YNyn0d11, a short-circuit impedance of HV-MV: 9.75%, a winding arrangement of LV-MV-HV-TV, a yield strength of 90 MPa for the medium-voltage winding, conductor dimensions of 2.24*12.5 mm for the medium-voltage winding, a reactance height of 1280 mm for the medium-voltage winding, and 20 strips in the medium-voltage winding. Here, LV denotes a low-voltage winding, MV denotes a medium-voltage winding, HV denotes a high-voltage winding, and TV denotes a regulating-voltage winding.

S2. A maximum short-circuit current passing through a transformer winding is acquired based on the transformer design parameter and the operating condition of the power system.

In this embodiment, the transformer design parameter includes a rated current of the transformer winding and a short-circuit impedance of the transformer; the operating condition of the power system where the transformer is located includes a short-circuit impedance of a grid system; and the maximum short-circuit current passing through the transformer winding is calculated by:

$${I}_{m} = {I}_{N} \times \frac{100}{{Z}_{T} + {Z}_{S}}$$

where, Iₘ denotes the maximum short-circuit current passing through the transformer winding; I_{N} denotes the rated current of the transformer winding; Z_{T} denotes the short-circuit impedance of the transformer; and Z_{S} denotes the short-circuit impedance of the grid system.

Furthermore, different types of transformers correspond to different short-circuit conditions. For a two-winding transformer, the short-circuit condition is high-voltage to low-voltage. For a three-winding transformer, the short-circuit condition includes four types: high-voltage to low-voltage, high-voltage to medium-voltage, medium-voltage to low-voltage, and high-voltage and medium-voltage to low-voltage. The acquired maximum short-circuit current passing through the transformer differs according to different conditions. Here, the expressions such as high-voltage to low-voltage, high-voltage to medium-voltage, and medium-voltage to low-voltage are commonly used in describing short-circuit conditions. They mean that one winding side is short-circuited while the other winding side serves as the power supply, thereby forming a short-circuit loop, or that the primary side serves as the power supply while the secondary side is short-circuited, as shown in FIG. 5. In FIG. 5, Uₙ denotes the rated voltage on the supply side of the transformer, and I_{d} denotes the short-circuit current. Illustratively, high-voltage and medium-voltage to low-voltage means that the high-voltage winding and medium-voltage winding are simultaneously powered as sources, while the low-voltage winding is short-circuited.

In a specific embodiment, the maximum short-circuit current passing through the transformer winding is 5.6 kA.

Thus, the maximum through-fault current experienced by the transformer winding under a short-circuit condition is acquired based on the short-circuit impedance of the grid system, the rated current of the transformer winding, and the short-circuit impedance of the transformer. This allows for a specific analysis on the short-circuit withstand capability of the transformer according to actual conditions, thereby improving calculation accuracy.

S3. The maximum short-circuit current passing through the transformer winding is input into a first preset calculation model, and a first stress value for each disc of the transformer winding is acquired, where the first preset calculation model is determined based on the transformer design parameter.

In this embodiment, the transformer design parameter includes an iron core structure parameter, a winding structure parameter based on ineffective radial support, a clamping structure parameter, and an oil tank parameter; and the first preset calculation model is a finite element structural model.

The finite element structural model is established based on the iron core structure parameter, the winding structure parameter based on ineffective radial support, the clamping structure parameter, and the oil tank parameter.

The maximum short-circuit current passing through the transformer winding is input into the finite element structural model, and the first stress value for each disc of the transformer winding is acquired.

In a specific embodiment, the finite element structural model is established based on the iron core structure parameter, the winding structure parameter based on ineffective radial support, the clamping structure parameter, and the oil tank parameter. Through finite element analysis software, a leakage flux B at different positions of the winding is calculated. According to a Lorentz force equation, an electromagnetic force F for different discs is acquired. Then, based on a cross-sectional parameter of a winding conductor and a material mechanics equation, the stress value for each disc of the transformer winding is calculated. Considering the transmission characteristics of disc electromagnetic forces, an average leakage flux is used for verification testing during calculation, i.e., the electromagnetic force and stress used for verification testing are average electromagnetic force and average stress value. Finally, the first stress value for each disc of the transformer winding is calculated. The first stress value for each disc of the transformer winding represents a radial stress value of the transformer winding under the maximum short-circuit current Iₘ. In a specific embodiment, the calculated first stress value for each disc of the transformer winding is 61.2 MPa.

Thus, the corresponding finite element structural model is established based on the iron core structure parameter of the transformer, the winding structure parameter based on ineffective radial support, the clamping structure parameter, and the oil tank parameter. This enables accurate calculation of the first stress value through finite element analysis software, reducing computational time, improving work efficiency, and enhancing the accuracy of testing results.

S4. A second stress value for each disc of the transformer winding is acquired by using a first predetermined method based on the transformer design parameter.

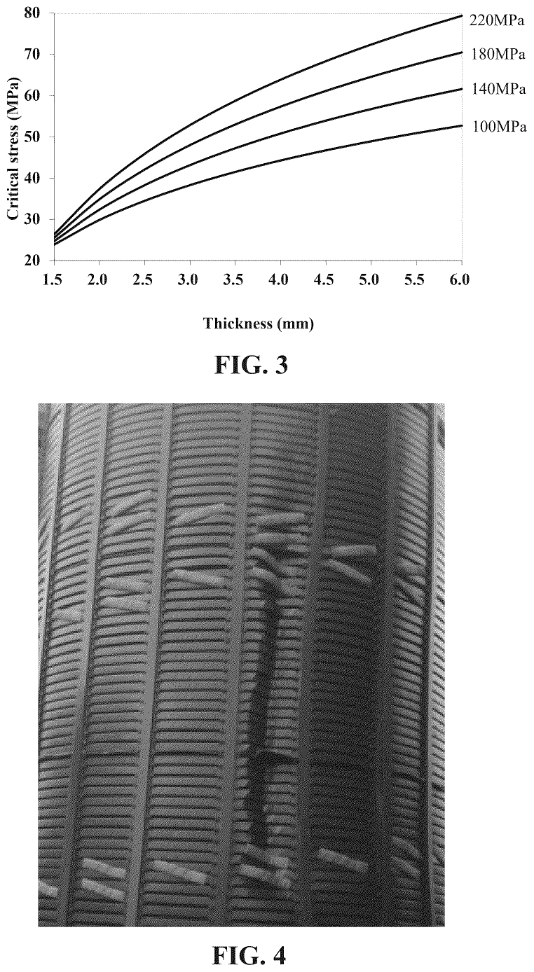

Please refer to FIG. 3, which is a diagram of a curve of a radial critical stress based on ineffective radial support in an embodiment of the method for testing a short-circuit withstand capability of a transformer provided by the present disclosure. In this embodiment, the transformer design parameter includes a yield strength and a thickness of a transformer conductor; and the second stress value for each disc of the transformer winding is determined according to:

$${σ}_{l} = ( A {σ}_{0.2} + B ) ln {b}_{e q} + C$$

where, σ₁ denotes the second stress value for each disc of the transformer winding; σ_{0.2} denotes the yield strength of the transformer conductor; b_{eq} denotes the thickness of the transformer conductor; and A, B, and C are preset coefficients. Specifically, the second stress value refers to a radial critical stress value of the transformer winding.

In a specific embodiment, the preset coefficient A ranges from 0.13 to 0.15; the preset coefficient B ranges from 6 to 8; and the preset coefficient C ranges from 12 to 15.

In a specific embodiment, the second stress value ranges from 26.3 to 32.3 MPa.

Thus, the preset coefficients set within specific numerical ranges for the corresponding calculations enables more accurate testing of the short-circuit withstand capability of the transformer.

S5. An allowable current of the transformer winding is acquired by using a second predetermined method based on the first stress value for each disc of the transformer winding and the second stress value for each disc of the transformer winding.

In this embodiment, the step that an allowable current of the transformer winding is acquired by using a second predetermined method based on the first stress value for each disc of the transformer winding and the second stress value for each disc of the transformer winding is specifically implemented as follows.

The maximum short-circuit current passing through the transformer winding is taken as an estimated allowable current.

It is determined whether the first stress value for each disc of the transformer winding equals the second stress value for each disc of the transformer winding.

The estimated allowable current is taken as the allowable current in response to that the first stress value for each disc of the transformer winding equals the second stress value for each disc of the transformer winding.

The estimated allowable current is updated in response to that the first stress value for each disc of the transformer winding does not equal the second stress value for each disc of the transformer winding.

An updated estimated allowable current is input into the first preset calculation model, an updated first stress value for each disc of the transformer winding is acquired, and this step returns to the step of determining whether the first stress value for each disc of the transformer winding equals the second stress value for each disc of the transformer winding, until the first stress value for each disc of the transformer winding equals the second stress value for each disc of the transformer winding.

In a specific embodiment, first, the maximum short-circuit current passing through the transformer winding is taken as the estimated allowable current. Then, it is determined whether the first stress value equals the second stress value. When the first stress value equals the second stress value, the estimated allowable current is taken as the allowable current. When the first stress value does not equal the second stress value, the estimated allowable current is adjusted, and the adjusted estimated allowable current is taken as the updated estimated allowable current. Then, the updated estimated allowable current is input into the first preset calculation model to acquire an updated first stress value, and it is determined again whether the first stress value equals the second stress value. If they are not equal, the estimated allowable current continues to be updated until the first stress value equals the second stress value. Then, this estimated allowable current can be taken as the allowable current of the transformer winding.

In a specific embodiment, the allowable current ranges from 3.7 to 4.1 kA, and the second stress value ranges from 26.3 to 32.3 MPa.

Thus, the corresponding estimated allowable current is acquired based on the first stress value, and then the accurate allowable current is acquired through the first preset calculation model. This design reduces the user's computational time and improves work efficiency.

S6. A safety factor of the transformer is acquired based on the allowable current of the transformer winding and the maximum short-circuit current passing through the transformer winding.

In a specific embodiment, the step that a safety factor of the transformer is acquired based on the allowable current of the transformer winding and the maximum short-circuit current passing through the transformer winding is specifically implemented according to:

$$K = \frac{{I}_{2}}{{I}_{m}}$$

where, K denotes the safety factor of the transformer; I₂ denotes the allowable current of the transformer winding; and Iₘ denotes the maximum short-circuit current passing through the transformer winding.

In a specific embodiment, the safety factor of the transformer ranges from 0.66 to 0.73. Reflecting the safety factor of the transformer through the ratio of currents allows for more accurate evaluation data. This enables a more accurate representation of the safety factor of the transformer, reducing errors caused by simulation and calculation.

S7. A short-circuit withstand capability of the transformer is determined based on the safety factor of the transformer.

In this embodiment, the step that a short-circuit withstand capability of the transformer is determined based on the safety factor of the transformer is specifically implemented as follows.

It is determined that the short-circuit withstand capability of the transformer is qualified in response to that the safety factor of the transformer is greater than a first threshold.

It is determined that the short-circuit withstand capability of the transformer is unqualified in response that the safety factor of the transformer is less than the first threshold.

In a specific embodiment, when the safety factor is greater than 1.0, it indicates that the short-circuit withstand capability of the transformer is qualified. A larger numerical value of the safety factor indicates a stronger short-circuit withstand capability of the transformer. When the safety factor of the transformer is less than 1.0, it indicates that the short-circuit withstand capability of the transformer is unqualified, and a smaller numerical value of the safety factor indicates a worse short-circuit withstand capability of the transformer. In some embodiments, when the safety factor equals 1.0, it indicates that the short-circuit withstand capability of the transformer is qualified.

S8. The transformer is controlled to shut down at a preset time when the short-circuit withstand capability of the transformer is unqualified.

In specific implementation, based on the safety factor of the transformer, an instruction for grid operation is provided to determine whether to modify an unqualified transformer through a scheduled power outage. Before the scheduled power outage, residents and enterprises in the relevant outage area need to be notified for the power outage at a preset time to minimize the impact on electrical equipment, residents, and enterprises. For example, when the short-circuit withstand capability of the transformer is unqualified, it indicates that the current transformer has a safety hazard, and a certain safety measure needs to be taken, such as controlling the transformer to shut down at a preset time, thereby effectively reducing the risk of operation failures in the power system. Here, the preset time refers to a time when the transformer is controlled to shut down, which can be determined based on the safety factor of the transformer or other practical needs. For instance, when the safety factor of the transformer is very low, indicating a significant safety hazard, a scheduled power outage needs to be scheduled in a short time.

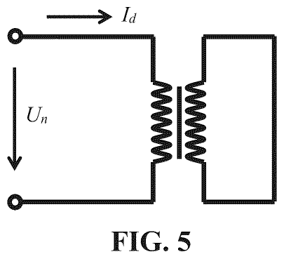

Please refer to FIG. 4, which is a diagram of a critical state of a transformer winding subjected to an allowable current in an embodiment of the method for testing a short-circuit withstand capability of a transformer provided by the present disclosure. In this embodiment, the safety factor ranges from 0.66 to 0.73, which is below a first threshold of 1.0, so it is determined that the short-circuit withstand capability of the transformer is unqualified.

Thus, by acquiring the transformer design parameter and the operating condition of the power system where the transformer is located, the maximum short-circuit current passing through the transformer winding is acquired. The maximum short-circuit current passing through the transformer is acquired based on the specific transformer design parameter and the voltage, current, and impedance of the power system where the transformer is located. This design enables more accurate testing of the short-circuit withstand capability of the transformer. Then, the acquired maximum short-circuit current passing through the transformer winding is input into the first preset calculation model, i.e., a finite element structural model to acquire the corresponding first stress value for each disc of the transformer winding. This design improves calculation accuracy, reduces calculation errors, and enhances computational efficiency. Subsequently, the second stress value for each disc of the transformer winding is acquired through the first predetermined method, enabling effective testing of the short-circuit withstand capability of the transformer. The allowable current is then acquired through the second predetermined method to acquire the safety factor of the transformer. By determining whether the safety factor exceeds a first threshold, the qualification of the short-circuit withstand capability of the transformer is determined. This allows for low-cost and high-efficiency determination of the short-circuit withstand capability of the transformer. In response to that the short-circuit withstand capability of the transformer is unqualified, the transformer is controlled to shut down at the preset time, thereby effectively reducing the risk of operation failures in the power system.

### Embodiment 2

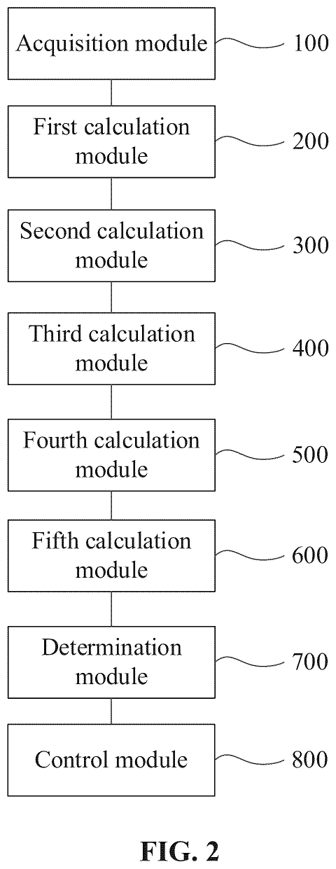

Please refer to FIG. 2, which is a structural diagram of an embodiment of a system for testing a short-circuit withstand capability of a transformer provided by the present disclosure. The system includes: an acquisition module 100, a first calculation module 200, a second calculation module 300, a third calculation module 400, a fourth calculation module 500, a fifth calculation module 600, a determination module 700, and a control module 800.

The acquisition module 100 is configured to acquire a transformer design parameter and an operating condition of a power system where the transformer is located.

In this embodiment, the acquisition module 100 acquires the transformer design parameter and the operating condition of the power system where the transformer is located, such that a specific analysis can be performed on the specific parameters of the transformer, improving the accuracy of short-circuit withstand capability testing. Then the operating condition of the power system where the transformer is located is combined, providing a realistic basis for the accurate testing of the short-circuit withstand capability, ensuring that the calculation results are targeted and practically relevant.

In a specific embodiment, taking a transformer model SSZ-40000/110 as an example, the transformer features a rated voltage of 121/40.5/10.5 kV, a connection group of YNyn0d11, a short-circuit impedance of HV-MV: 9.75%, a winding arrangement of LV-MV-HV-TV, a yield strength of 90 MPa for the medium-voltage winding, conductor dimensions of 2.24*12.5 mm for the medium-voltage winding, a reactance height of 1280 mm for the medium-voltage winding, and 20 strips in the medium-voltage winding. Here, LV denotes a low-voltage winding, MV denotes a medium-voltage winding, HV denotes a high-voltage winding, and TV denotes a regulating-voltage winding.

The first calculation module 200 is configured to acquire a maximum short-circuit current passing through the transformer winding based on the transformer design parameter and the operating condition of the power system where the transformer is located.

In this embodiment, the transformer design parameter includes a rated current of the transformer winding and a short-circuit impedance of the transformer. The operating condition of the power system where the transformer is located includes a short-circuit impedance of a grid system. The first calculation module 200 is configured to calculate the maximum short-circuit current passing through the transformer winding by:

$${I}_{m} = {I}_{N} \times \frac{100}{{Z}_{T} + {Z}_{S}}$$

where, Iₘ denotes the maximum short-circuit current passing through the transformer winding; I_{N} denotes the rated current of the transformer winding; Z_{T} denotes the short-circuit impedance of the transformer; and Z_{S} denotes the short-circuit impedance of the grid system.

Furthermore, different types of transformers correspond to different short-circuit conditions. For a two-winding transformer, the short-circuit condition is high-voltage to low-voltage. For a three-winding transformer, the short-circuit condition includes four types: high-voltage to low-voltage, high-voltage to medium-voltage, medium-voltage to low-voltage, and high-voltage+medium-voltage to low-voltage. The acquired maximum short-circuit current of the transformer differs according to different conditions. Here, the expressions such as high-voltage to low-voltage, high-voltage to medium-voltage, and medium-voltage to low-voltage are commonly used in describing short-circuit conditions. They mean that one winding side is short-circuited while the other winding side is powered, thereby forming a short-circuit loop, or that the primary side is powered while the secondary side is short-circuited, as shown in FIG. 5. Illustratively, high-voltage+medium-voltage to low-voltage means that the high-voltage winding and medium-voltage winding are simultaneously powered as sources, while the low-voltage winding is short-circuited.

In a specific embodiment, the maximum short-circuit current passing through the transformer winding is 5.6 kA.

Thus, the first calculation module 200 acquires the maximum through-fault current experienced by the transformer winding under a short-circuit condition based on the short-circuit impedance of the grid system, the rated current of the transformer winding, and the short-circuit impedance of the transformer. This allows for a specific analysis on the short-circuit withstand capability of the transformer according to actual conditions, thereby improving calculation accuracy.

The second calculation module 300 is configured to input the maximum short-circuit current passing through the transformer winding into a first preset calculation model and acquire a first stress value for each disc of the transformer winding, where the first preset calculation model is determined based on the transformer design parameter.

In this embodiment, the transformer design parameter includes an iron core structure parameter, a winding structure parameter based on ineffective radial support, a clamping structure parameter, and an oil tank parameter; and the first preset calculation model is a finite element structural model.

The finite element structural model is established based on the iron core structure parameter, the winding structure parameter based on ineffective radial support, the clamping structure parameter, and the oil tank parameter.

The second calculation module 300 is specifically configured to input the maximum short-circuit current passing through the transformer winding into the finite element structural model and acquire the first stress value for each disc of the transformer winding.

In a specific embodiment, the finite element structural model is established based on the iron core structure parameter, the winding structure parameter based on ineffective radial support, the clamping structure parameter, and the oil tank parameter. Through finite element analysis software, a leakage flux B at different positions of the winding is calculated. According to a Lorentz force equation, an electromagnetic force F for different discs is acquired. Then, based on a cross-sectional parameter of a winding conductor and a material mechanics equation, the stress value for each disc of the transformer winding is calculated. Considering the transmission characteristics of disc electromagnetic forces, an average leakage flux is used for verification testing during calculation, i.e., the electromagnetic force and stress used for verification testing are average electromagnetic force and average stress value. Finally, the first stress value for each disc of the transformer winding is calculated. The first stress value for each disc of the transformer winding represents a radial stress value of the transformer winding under the maximum short-circuit current Iₘ. In a specific embodiment, the calculated first stress value for each disc of the transformer winding is 61.2 MPa.

Thus, the second calculation module 300 establishes the corresponding finite element structural model based on the iron core structure parameter of the transformer, the winding structure parameter based on ineffective radial support, the clamping structure parameter, and the oil tank parameter. This enables accurate calculation of the first stress value through finite element analysis software, reducing computational time, improving work efficiency, and enhancing the accuracy of testing results.

The third calculation module 400 is configured to acquire a second stress value for each disc of the transformer winding by using a first predetermined method based on the transformer design parameter.

Please refer to FIG. 3, which is a diagram of a curve of a radial critical stress based on ineffective radial support in the present disclosure. In this embodiment, the transformer design parameter includes a yield strength and a thickness of a transformer conductor; and the second stress value for each disc of the transformer winding is determined according to:

$${σ}_{l} = ( A {σ}_{0.2} + B ) ln {b}_{e q} + C$$

where, σ₁ denotes the second stress value for each disc of the transformer winding; σ_{0.2} denotes the yield strength of the transformer conductor; b_{eq} denotes the thickness of the transformer conductor; and A, B, and C are preset coefficients. Specifically, the second stress value refers to a radial critical stress value of the transformer winding.

In a specific embodiment, the preset coefficient A ranges from 0.13 to 0.15; the preset coefficient B ranges from 6 to 8; and the preset coefficient C ranges from 12 to 15.

In a specific embodiment, the second stress value ranges from 26.3 to 32.3 MPa.

Thus, the third calculation module 400 performs corresponding calculations according to the preset coefficients set within specific numerical ranges, enabling more accurate testing of the short-circuit withstand capability of the transformer.

The fourth calculation module 500 is configured to acquire an allowable current of the transformer winding by using a second predetermined method based on the first stress value for each disc of the transformer winding and the second stress value for each disc of the transformer winding.

In this embodiment, the step that an allowable current of the transformer winding is acquired by using a second predetermined method based on the first stress value for each disc of the transformer winding and the second stress value for each disc of the transformer winding is specifically implemented as follows.

The maximum short-circuit current passing through the transformer winding is taken as an estimated allowable current.

It is determined whether the first stress value for each disc of the transformer winding equals the second stress value for each disc of the transformer winding.

The estimated allowable current is taken as the allowable current in response to that the first stress value for each disc of the transformer winding equals the second stress value for each disc of the transformer winding.

The estimated allowable current is updated in response to that the first stress value for each disc of the transformer winding does not equal the second stress value for each disc of the transformer winding.

An updated estimated allowable current is input into the first preset calculation model, an updated first stress value for each disc of the transformer winding is acquired, and this step returns to the step of determining whether the first stress value for each disc of the transformer winding equals the second stress value for each disc of the transformer winding, until the first stress value for each disc of the transformer winding equals the second stress value for each disc of the transformer winding.

In a specific embodiment, first, the maximum short-circuit current passing through the transformer winding is taken as the estimated allowable current. Then, it is determined whether the first stress value equals the second stress value. When the first stress value equals the second stress value, the estimated allowable current is taken as the allowable current. When the first stress value does not equal the second stress value, the estimated allowable current is adjusted, and the adjusted estimated allowable current is taken as the updated estimated allowable current. Then, the updated estimated allowable current is input into the first preset calculation model to acquire an updated first stress value, and it is determined again whether the first stress value equals the second stress value. If they are not equal, the estimated allowable current continues to be updated until the first stress value equals the second stress value. Then, this estimated allowable current can be taken as the allowable current of the transformer winding.

In a specific embodiment, the allowable current ranges from 3.7 to 4.1 kA, and the second stress value ranges from 26.3 to 32.3 MPa.

Thus, the fourth calculation module 500 acquires the corresponding estimated allowable current based on the first stress value and then acquires the accurate allowable current through the first preset calculation model. This design reduces the user's computational time and improves work efficiency.

The fifth calculation module 600 is configured to acquire a safety factor of the transformer based on the allowable current of the transformer winding and the maximum short-circuit current passing through the transformer winding.

In a specific embodiment, the step that a safety factor of the transformer is acquired based on the allowable current of the transformer winding and the maximum short-circuit current passing through the transformer winding is specifically implemented according to:

$$K = \frac{{I}_{2}}{{I}_{m}}$$

where, K denotes the safety factor; I₂ denotes the allowable current of the transformer winding; and Iₘ denotes the maximum short-circuit current passing through the transformer winding.

In a specific embodiment, the fifth calculation module 600 calculates the safety factor of the transformer as ranges from 0.66 to 0.73. Reflecting the safety factor of the transformer through the ratio of currents allows for more accurate evaluation data. This enables a more accurate representation of the safety factor of the transformer, reducing errors caused by simulation and calculation.

The determination module 700 is configured to determine a short-circuit withstand capability of the transformer based on the safety factor of the transformer.

In this embodiment, the step that a short-circuit withstand capability of the transformer is determined based on the safety factor of the transformer is specifically implemented as follows.

It is determined that the short-circuit withstand capability of the transformer is qualified in response to that the safety factor of the transformer is greater than a first threshold.

It is determined that the short-circuit withstand capability of the transformer is unqualified when the safety factor of the transformer is less than the first threshold.

In a specific embodiment, when the safety factor is greater than 1.0, it indicates that the short-circuit withstand capability of the transformer is qualified. A larger numerical value of the safety factor indicates a stronger short-circuit withstand capability of the transformer. When the safety factor of the transformer is less than 1.0, it indicates that the short-circuit withstand capability of the transformer is unqualified, and a smaller numerical value of the safety factor indicates a worse short-circuit withstand capability of the transformer. In some embodiments, when the safety factor equals 1.0, it indicates that the short-circuit withstand capability of the transformer is qualified.

The control module 800 is configured to control the transformer to shut down at a preset time in response to that the short-circuit withstand capability of the transformer is unqualified.

In specific implementation, based on the safety factor of the transformer, an instruction for grid operation is provided to determine whether to modify an unqualified transformer through a scheduled power outage. Before the power scheduled outage, residents and enterprises in the relevant outage area need to be notified for the power outage at a preset time to minimize the impact on electrical equipment, residents, and enterprises. For example, when the short-circuit withstand capability of the transformer is unqualified, it indicates that the current transformer has a safety hazard, and a certain safety measure needs to be taken, such as controlling the transformer to shut down at a preset time, thereby effectively reducing the risk of operation failures in the power system. Here, the preset time refers to a time when the transformer is controlled to shut down, which can be determined based on the safety factor of the transformer or other practical needs. For instance, when the safety factor of the transformer is very low, indicating a significant safety hazard, a scheduled power outage needs to be scheduled in a short time.

Please refer to FIG. 4, which is a diagram of a critical state of a transformer winding subjected to an allowable current in an embodiment of the method for testing a short-circuit withstand capability of a transformer provided by the present disclosure. In this embodiment, the safety factor ranges from 0.66 to 0.73, which is below a first threshold of 1.0, so it is determined that the short-circuit withstand capability of the transformer is unqualified.

Thus, the acquisition module 100 acquires the transformer design parameter and the operating condition of the power system where the transformer is located, and then the first calculation module 200 acquires the maximum short-circuit current passing through the transformer winding. On this basis, the maximum short-circuit current passing through the transformer is calculated based on the specific transformer design parameter and the voltage, current, and impedance of the power system. This design enables more accurate testing of the short-circuit withstand capability of the transformer. Then, the second calculation module 300 inputs the acquired maximum short-circuit current into the first preset calculation model, i.e., a finite element structural model, to acquire the corresponding first stress value for each disc of the transformer winding. This design improves calculation accuracy, reduces calculation errors, and enhances computational efficiency. The third calculation module 400 acquires the second stress value for each disc of the transformer winding, enabling effective testing of the short-circuit withstand capability of the transformer. The fourth calculation module 500 acquires the allowable current, and then the fifth calculation module 600 acquires the safety factor of the transformer. The determination module 700 determines whether the safety factor exceeds a first threshold to determine the qualification of the short-circuit withstand capability of the transformer. This allows for low-cost and high-efficiency determination of the short-circuit withstand capability of the transformer, and effectively reduces the risk of operation failures in the power system.

In the embodiment of the present disclosure, the acquisition module 100, the first calculation module 200, the second calculation module 300, the third calculation module 400, the fourth calculation module 500, the fifth calculation module 600, the determination module 700, and the control module 800 may each include one or more processors, controllers, or chips with communication interfaces capable of implementing communication protocols, and may further include memory and related interfaces, system transmission buses, etc., if needed. The processors, controllers, or chips execute program-related code to implement corresponding functions. Alternatively, in a replaceable solution, the acquisition module 100, the first calculation module 200, the second calculation module 300, the third calculation module 400, the fourth calculation module 500, the fifth calculation module 600, the determination module 700, and the control module 800 share an integrated chip or share devices such as the processor, controller, and memory. The shared processor, controller, or chip is configured to execute program-related code to implement corresponding functions.

### Embodiment 3

This embodiment of the present disclosure further provides a terminal device, including a processor, a memory, and a computer program stored in and run on the memory, where the processor is configured to execute the computer program, thereby implementing the steps of the method for testing a short-circuit withstand capability of a transformer described in any embodiment of the present disclosure

### Embodiment 4

This embodiment of the present disclosure further provides a non-transitory computer-readable storage medium, configured to store a computer program, where the computer program is executed by a processor to implement the steps of the method for testing a short-circuit withstand capability of a transformer described in any embodiment of the present disclosure.

### Embodiment 5

This embodiment of the present disclosure further provides a computer program product, including a non-transitory computer-readable storage medium with computer-readable program code, where the computer-readable program code is executed by a processor to implement the steps of the method for testing a short-circuit withstand capability of a transformer described in any embodiment of the present disclosure.

The system embodiment described above is merely illustrative. Units described as separate components may or may not be physically separate. That is, they may be located in one place or distributed across a plurality of network units. Some or all of the modules may be selected according to actual needs to achieve the objectives of the solution in the embodiment.

Those of ordinary skill in the art can understand that all or some of the steps in the method, or the system disclosed above, may be implemented as software, firmware, hardware, or a suitable combination thereof. Some or all physical components may be implemented as software executed by a processor, such as a central processing unit, a digital signal processor, or a microprocessor; or as hardware; or as an integrated circuit, such as an application-specific integrated circuit. Such software may be distributed on a computer-readable medium, which may include computer storage media (or non-transitory media) and communication media (or transitory media). As well known to those of ordinary skill in the art, the term computer storage media includes volatile and non-volatile, removable and non-removable media implemented in any method or technology for storing information (such as computer-readable instructions, data structures, program modules, or other data). Computer storage media include, but are not limited to, random access memory (RAM), read-only memory (ROM), electrically erasable programmable read-only memory (EEPROM), flash memory or other memory technologies, compact disc read-only memory (CD-ROM), digital versatile disc (DVD) or other optical disc storage, magnetic cassettes, magnetic tapes, magnetic disc storage or other magnetic storage devices, or any other medium that can be used to store desired information and can be accessed by a computer. Furthermore, it is well known to those of ordinary skill in the art that communication media typically embody computer-readable instructions, data structures, program modules, or other data in a modulated data signal, such as a carrier wave or other transport mechanism, and may include any information delivery medium.

In the description of this specification, descriptions about such reference terms as “an embodiment”, “some embodiments”, “an example”, “a specific example”, and “some examples” mean that specific features, structures, materials, or characteristics described with reference to the embodiments or examples are included in at least one embodiment or example of the present disclosure. Moreover, the specific features, structures, materials, or characteristics described may be combined in a suitable manner in any one or more embodiments or examples. In addition, those skilled in the art may combine different embodiments or examples described in this specification and characteristics of the different embodiments or examples without mutual contradiction.

In addition, the terms such as “first” and “second” are used only for descriptive purposes, and should not be construed as indicating or implying relative importance or implying the number of indicated technical features. Therefore, features defined by “first” and “second” may explicitly or implicitly include at least one of the features. In the description of the present disclosure, “a plurality of” means two or more, unless otherwise specifically defined.

Any process or method description in the flowchart or described in other manners herein can be understood as representing a module, segment, or part of code that includes one or more executable instructions for implementing steps of specific logical functions or steps of the process. In addition, the scope of the preferred implementations of the present disclosure includes additional implementations, which may not be in the order shown or discussed, including performing functions in a substantially simultaneous manner or in a reverse order according to the functions involved. This should be understood by a person skilled in the art to which the embodiments of the present disclosure belong.

Logic and/or steps shown in the flowcharts or described herein in other manners, for example, may be considered as a program list of executable instructions that are used to implement logical functions, and may be specifically implemented on any computer-readable medium, for an instruction execution system, apparatus, or device (for example, a computer-based system, a system including a processor, or another system that can fetch instructions from the instruction execution system, apparatus, or device and execute the instructions) to use, or for a combination of the instruction execution system, apparatus, or device to use. For the purposes of this specification, a “computer-readable medium” may be any apparatus that can contain, store, communicate, propagate, or transmit a program for use by instruction execution systems, apparatuses, or devices or in combination with these instruction execution systems, apparatuses, or devices.

The objectives, technical solutions, and beneficial effects of the present disclosure are further described in detail through the above specific embodiments. It should be understood that the above are merely some specific embodiments of the present disclosure, but are not intended to limit the protection scope of the present disclosure. It should be particularly noted that, any modifications, equivalent substitutions, improvements, and the like made by those skilled in the art within the spirit and principle of the present disclosure should be included within the protection scope of the present disclosure.

1. A method for testing a short-circuit withstand capability of a transformer, comprising:
acquiring a transformer design parameter and an operating condition of a power system where a transformer is located;
acquiring a maximum short-circuit current passing through a transformer winding based on the transformer design parameter and the operating condition of the power system where the transformer is located;
inputting the maximum short-circuit current passing through the transformer winding into a first preset calculation model, and acquiring a first stress value for each disc of the transformer winding, wherein the first preset calculation model is determined based on the transformer design parameter;
acquiring a second stress value for each disc of the transformer winding by using a first predetermined method based on the transformer design parameter;
acquiring an allowable current of the transformer winding by using a second predetermined method based on the first stress value for each disc of the transformer winding and the second stress value for each disc of the transformer winding;
acquiring a safety factor of the transformer based on the allowable current of the transformer winding and the maximum short-circuit current passing through the transformer winding;
determining a short-circuit withstand capability of the transformer based on the safety factor of the transformer; and
controlling the transformer to shut down at a preset time in response to that the short-circuit withstand capability of the transformer is unqualified.

2. The method for testing a short-circuit withstand capability of a transformer according to claim 1, wherein the transformer design parameter comprises a rated current of the transformer winding and a short-circuit impedance of the transformer; the operating condition of the power system where the transformer is located comprises a short-circuit impedance of a grid system; and the maximum short-circuit current passing through the transformer winding is calculated by:
$${I}_{m} = {I}_{N} \times \frac{100}{{Z}_{T} + {Z}_{S}}$$
wherein, Iₘ denotes the maximum short-circuit current passing through the transformer winding; I_{N} denotes the rated current of the transformer winding; Z_{T} denotes the short-circuit impedance of the transformer; and Z_{S} denotes the short-circuit impedance of the grid system.

3. The method for testing a short-circuit withstand capability of a transformer according to claim 1, wherein the transformer design parameter comprises an iron core structure parameter, a winding structure parameter based on ineffective radial support, a clamping structure parameter, and an oil tank parameter; and the first preset calculation model is a finite element structural model;
the finite element structural model is established based on the iron core structure parameter, the winding structure parameter based on ineffective radial support, the clamping structure parameter, and the oil tank parameter; and
the inputting the maximum short-circuit current passing through the transformer winding into a first preset calculation model, and acquiring a first stress value for each disc of the transformer winding comprises:
inputting the maximum short-circuit current passing through the transformer winding into the finite element structural model, and acquiring the first stress value for each disc of the transformer winding.

4. The method for testing a short-circuit withstand capability of a transformer according to claim 1, wherein the transformer design parameter comprises a yield strength and a thickness of a transformer conductor; and the second stress value for each disc of the transformer winding is determined according to:
$${σ}_{l} = ( A {σ}_{0.2} + B ) ln {b}_{e q} + C$$
wherein, σ₁ denotes the second stress value for each disc of the transformer winding; σ_{0.2} denotes the yield strength of the transformer conductor; b_{eq} denotes the thickness of the transformer conductor; and A, B, and C are preset coefficients.

5. The method for testing a short-circuit withstand capability of a transformer according to claim 4, wherein the preset coefficient A ranges from 0.13 to 0.15; the preset coefficient B ranges from 6 to 8; and the preset coefficient C ranges from 12 to 15.

6. The method for testing a short-circuit withstand capability of a transformer according to claim 1, wherein the acquiring an allowable current of the transformer winding by using a second predetermined method based on the first stress value for each disc of the transformer winding and the second stress value for each disc of the transformer winding comprises:
taking the maximum short-circuit current passing through the transformer winding as an estimated allowable current;
determining whether the first stress value for each disc of the transformer winding equals the second stress value for each disc of the transformer winding;
taking the estimated allowable current as the allowable current in response to that the first stress value for each disc of the transformer winding equals the second stress value for each disc of the transformer winding;
updating the estimated allowable current in response to that the first stress value for each disc of the transformer winding does not equal the second stress value for each disc of the transformer winding; and
inputting an updated estimated allowable current into the first preset calculation model, acquiring an updated first stress value for each disc of the transformer winding, and returning to the step of determining whether the first stress value for each disc of the transformer winding equals the second stress value for each disc of the transformer winding, until the first stress value for each disc of the transformer winding equals the second stress value for each disc of the transformer winding.

7. The method for testing a short-circuit withstand capability of a transformer according to claim 1, wherein the acquiring a safety factor of the transformer based on the allowable current of the transformer winding and the maximum short-circuit current passing through the transformer winding is implemented according to:
$$K = \frac{{I}_{2}}{{I}_{m}}$$
wherein, K denotes the safety factor; I₂ denotes the allowable current; and Iₘ denotes the maximum short-circuit current passing through the transformer winding.

8. The method for testing a short-circuit withstand capability of a transformer according to claim 1, wherein the determining a short-circuit withstand capability of the transformer based on the safety factor of the transformer specifically comprises:
determining that the short-circuit withstand capability of the transformer is qualified in response to that the safety factor of the transformer is greater than a first threshold; and
determining that the short-circuit withstand capability of the transformer is unqualified in response to that the safety factor of the transformer is less than the first threshold.

9. A system for testing a short-circuit withstand capability of a transformer, comprising: an acquisition module, a first calculation module, a second calculation module, a third calculation module, a fourth calculation module, a fifth calculation module, a determination module, and a control module, wherein
the acquisition module is configured to acquire a transformer design parameter and an operating condition of a power system where a transformer is located;
the first calculation module is configured to acquire a maximum short-circuit current passing through a transformer winding based on the transformer design parameter and the operating condition of the power system where the transformer is located;
the second calculation module is configured to input the maximum short-circuit current passing through the transformer winding into a first preset calculation model and acquire a first stress value for each disc of the transformer winding, wherein the first preset calculation model is determined based on the transformer design parameter;
the third calculation module is configured to acquire a second stress value for each disc of the transformer winding by using a first predetermined method based on the transformer design parameter;
the fourth calculation module is configured to acquire an allowable current of the transformer winding by using a second predetermined method based on the first stress value for each disc of the transformer winding and the second stress value for each disc of the transformer winding;
the fifth calculation module is configured to acquire a safety factor of the transformer based on the allowable current of the transformer winding and the maximum short-circuit current passing through the transformer winding;
the determination module is configured to determine a short-circuit withstand capability of the transformer based on the safety factor of the transformer; and
the control module is configured to control the transformer to shut down at a preset time in response to that the short-circuit withstand capability of the transformer is unqualified.

10. A terminal device, comprising: a processor, a memory, and a computer program stored in and run on the memory, wherein the processor is configured to execute the computer program, thereby implementing the steps of the method for testing a short-circuit withstand capability of a transformer according to claim 1.

11. A terminal device, comprising: a processor, a memory, and a computer program stored in and run on the memory, wherein the processor is configured to execute the computer program, thereby implementing the steps of the method for testing a short-circuit withstand capability of a transformer according to claim 2.

12. A terminal device, comprising: a processor, a memory, and a computer program stored in and run on the memory, wherein the processor is configured to execute the computer program, thereby implementing the steps of the method for testing a short-circuit withstand capability of a transformer according to claim 3.

13. A terminal device, comprising: a processor, a memory, and a computer program stored in and run on the memory, wherein the processor is configured to execute the computer program, thereby implementing the steps of the method for testing a short-circuit withstand capability of a transformer according to claim 4.

14. A terminal device, comprising: a processor, a memory, and a computer program stored in and run on the memory, wherein the processor is configured to execute the computer program, thereby implementing the steps of the method for testing a short-circuit withstand capability of a transformer according to claim 5.

15. A terminal device, comprising: a processor, a memory, and a computer program stored in and run on the memory, wherein the processor is configured to execute the computer program, thereby implementing the steps of the method for testing a short-circuit withstand capability of a transformer according to claim 6.

16. A terminal device, comprising: a processor, a memory, and a computer program stored in and run on the memory, wherein the processor is configured to execute the computer program, thereby implementing the steps of the method for testing a short-circuit withstand capability of a transformer according to claim 7.

17. A terminal device, comprising: a processor, a memory, and a computer program stored in and run on the memory, wherein the processor is configured to execute the computer program, thereby implementing the steps of the method for testing a short-circuit withstand capability of a transformer according to claim 8.

18. A non-transitory computer-readable storage medium, configured to store a computer program, wherein the computer program is executed by a processor to implement the steps of the method for testing a short-circuit withstand capability of a transformer according to claim 1.

19. A non-transitory computer-readable storage medium, configured to store a computer program, wherein the computer program is executed by a processor to implement the steps of the method for testing a short-circuit withstand capability of a transformer according to claim 2.

20. A computer program product, comprising: a non-transitory computer-readable storage medium with computer-readable program code, wherein the computer-readable program code is executed by a processor to implement the steps of the method for testing a short-circuit withstand capability of a transformer according to claim 1.
